(19) United States
(12) Patent Application Publication
(10) Pub. No.: US 2021/0185446 A1
(43) Pub. Date: Jun. 17, 2021

(54) SYSTEM AND METHOD FOR CUSTOMIZING SOUND AND EQUALIZATION FOR AUDIO DEVICES

(71) Applicants: Troy Douglas Calderwood, Wellsville, KS (US); Barrett Prelogar, Overland Park, KS (US)

(72) Inventors: Troy Douglas Calderwood, Wellsville, KS (US); Barrett Prelogar, Overland Park, KS (US)

(21) Appl. No.: 17/126,014

(22) Filed: Dec. 17, 2020

Related U.S. Application Data
(60) Provisional application No. 62/949,059, filed on Dec. 17, 2019.

(51) Int. Cl. H04R 5/04; H04S 7/00; H03G 5/02; H04R 3/04

(52) U.S. Cl. CPC H04R 5/04; H04R 3/04; H03G 5/025; H04S 7/301

(57) ABSTRACT

An automated equalization control module is operable to adjust the equalization settings of a hearable device or music playback application based on one or more data parameters in the metadata associated with the audio content being played. The sonic characteristics of the playback are adjusted based on user-defined preferences associated with one or more metadata tags.

### CROSS-REFERENCE TO RELATED APPLICATIONS

This application claims the benefit of U.S. Provisional Patent Application No. 62/949,059, filed Dec. 17, 2019, the disclosure of which is hereby incorporated herein in its entirety by reference.

### BACKGROUND

Audio content is recorded and played using various equipment and various recording and playback parameters, resulting in great variation in the sonic characteristics of audio content a consumer hears when listening to a played-back recording.

For example, the sound and equalization parameters employed in recording and mastering sound recordings of bands in the 1960's differ greatly from sound and equalization parameters employed in recording and mastering sound recordings of bands today, in part because the recording facilities, recording equipment, playback equipment, and method of transmitting the sound recording are markedly different today than they were decades ago. End listeners, however, may have different listening or performance objectives which are incongruent with those utilized in the original recording and engineering process.

In addition to different sound and equalization parameters imparted by equipment differences, different artists and producers have varying preferences for their sound recordings, and differing musical genres typically employ differing sound and equalization parameters to achieve a desired sound recording.

Consumers thus often discover that sound and equalization settings must be changed between songs, pod casts, or other played or streamed audio content in order to optimize their listening experience. This process is invariably cumbersome, or even impossible to do, often requiring the user to open a settings application on their phone, or music player app or device every time they listen to a different track to either recall previously saved settings, or to reset the settings manually.

Thus, it can be seen that there remains a need in the art for a system and method that allow a user to customize sound and equalization settings for listening to audio content without the need to manually select or adjust those settings each time different content is played.

### SUMMARY

A high-level overview of various aspects of exemplary embodiments is provided in this section to introduce a selection of concepts that are further described in the detailed description section below. This summary is not intended to identify key features or essential features of exemplary embodiments, nor is it intended to be used in isolation to determine the scope of the described subject matter. In brief, this disclosure describes a system and method for automatically adjusting sound and equalization parameters of audio playback devices and audio playback applications based on metadata associated with the audio content being played, thus relieving a user from the necessity of manually adjusting the sound and equalization parameters for varying content.

Modern digital audio content includes metadata—i.e., information associated with the audio content—that is transmitted along with the audio content to a playback device or playback application running on a smartphone, computer, tablet, vehicle audio system, or the like. The metadata typically includes information such as the song title (or title of the audio content if not a song, such as a book name for an audio book, etc.), artist's name, album name, genre, songwriter, and various other information associated with the audio content. The metadata is typically contained in a common format, such as ID3v1 or ID3v2, with audio playback devices and applications configured to receive the transmitted metadata to, for example, display the name of the song and artist as the audio content is playing.

Playback of modern audio content may be accomplished on a “hearable” device, i.e., smart or computer-enabled earphones, earbuds, headphones, and speakers, that translate the audio content data stream into an audible sound wave for enjoyment by the user. Consumers use various hearable devices to listen to their music, podcasts, and other audio content. In addition to translating audio content to audible sound waves (as a simple audio speaker does), hearable devices may include radio receivers and microprocessors, DSP's (digital signal processors), and other audio control and equalization circuitry operable to tune the sonic performance of the hearable device to achieve a desired sound experience for a user.

In one aspect of the present invention, an automated equalization control module comprises a processor and memory, and is operable to adjust or readjust the equalization, gain, and other audio playback parameter automatically to correspond with stored settings associated with a metadata field value contained within any one of a plurality of the metadata fields associated with the particular audio content to be played, or within multiple of those plurality of metadata fields. For example, a user may prefer that songs by a particular artist have increased treble, thus upon detection of that artist name in the metadata, the automated equalization control module adjusts the settings of the equalizer to achieve the user's desired equalization setting for that artist.

In further aspects, the automated equalization control modules may reside on a source device, on an audio output rendering device, or at a content provider. Various embodiments of automated equalization control modules are described herein.

In further embodiments, sensors on the hearable device may provide further metadata or signals to the automated equalization control module which may be incorporated into the user rules for applying equalization settings. For example, a microphone or sound pressure level sensor incorporated on a wearable hearable device, such as headphones, may provide a signal indicative of an ambient noise level to the automated equalization control module, with a user rule providing that when the ambient noise level is above a particular threshold, the equalization level may be adjusted to increase a desired frequency band and/or the volume may be adjusted to allow a user to more easily hear, for example, an audio book.

### DESCRIPTION OF THE DRAWINGS

Illustrative embodiments are described in detail below with reference to the attached drawing figures, and wherein:

FIG. 1 is a block diagram of an automated equalization control module embedded in an audio output rendering device in accordance with a first exemplary embodiment of the present invention.

FIG. 2 is a flow diagram of an exemplary method of customizing sound and equalization for audio device in accordance with an exemplary embodiment of the present invention.

FIG. 3 is a block diagram of an automated equalization control module implemented in a source device in accordance with a second exemplary embodiment of the present invention.

FIG. 4 is a block diagram of an automated equalization control module with an external database in accordance with a fourth exemplary embodiment of the present invention.

FIG. 5 is a block diagram of an automated equalization control module in accordance with a fifth exemplary embodiment of the present invention.

### DETAILED DESCRIPTION

The subject matter of select exemplary embodiments is described with specificity herein to meet statutory requirements. But the description itself is not intended to necessarily limit the scope of embodiments thereof. Rather, the subject matter might be embodied in other ways to include different components, steps, or combinations thereof similar to the ones described in this document, in conjunction with other present or future technologies. Terms should not be interpreted as implying any particular order among or between various steps herein disclosed unless and except when the order of individual steps is explicitly described. The terms “about” or “approximately” as used herein denote deviations from the exact value by +/−10%, preferably by +/−5% and/or deviations in the form of changes that are insignificant to the function.

The invention will be described herein with respect to several exemplary embodiments. It should be understood that these embodiments are exemplary, and not limiting, and that variations of these embodiments are within the scope of the present invention.

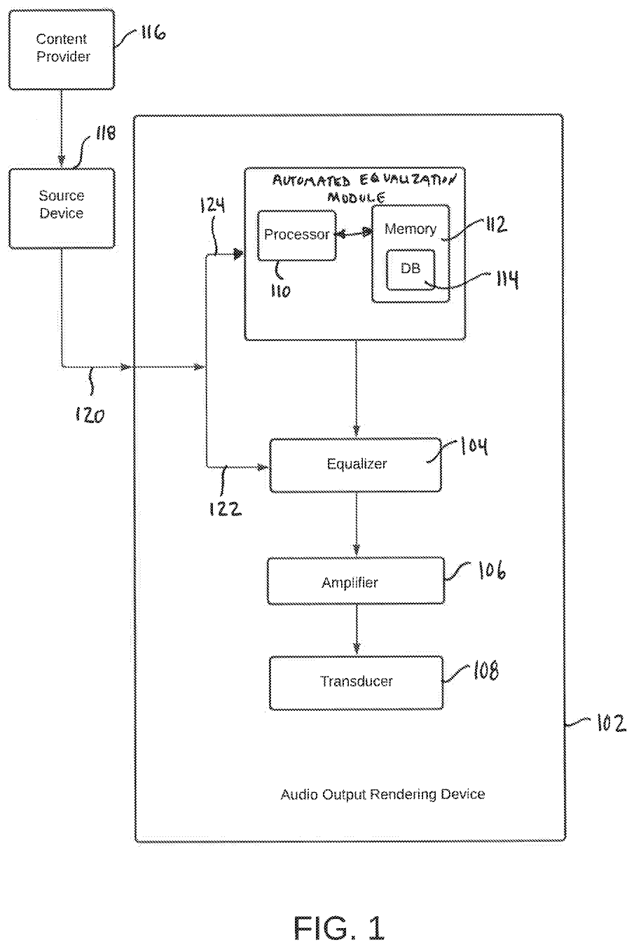

Looking first to FIG. 1, an automated equalization control module in accordance with a first exemplary embodiment of the present invention is depicted by the numeral 100. In this embodiment, the automated equalization control module 100 is embedded in an audio output rendering device 102 such as a hearable device. The audio output rendering device 102 may be any type of device capable of rendering an audible sound from an audio content signal. Examples of hearable devices include smartphones, laptop and desktop computers, tablets, headphones, earphones, speakers, commercial sound systems, or any other device configured to translate an audio content signal to an audible soundwave for listening by a user.

The audio output rendering device 102 includes an equalizer 104 operable to adjust the sonic characteristics of an audio signal to achieve a desired sound for a listener, an amplifier 106 to amplify an audio signal to a desired level, and a transducer 108, such as a speaker, to translate the audio signal to an audible sound wave.

It should be understood that these modules and functions may be accomplished via hardware, software, and combinations thereof. It should be further understood that the identification of a separate equalizer module 104, amplifier 106, and transducer 108 in the audio output rendering device 102 is for exemplary and explanatory purposes, and that in practice there may be overlap between the hardware and/or software used in implementing those modules and functions.

Regardless of the physical or virtual configuration the automated equalization control module 100 is operable to set, reset, and or adjust the equalizer 104 to achieve desired settings of that equalizer module.

Looking still to FIG. 1, automated equalization module 100 comprises a processor 110 in communication with a memory device 112. Memory device 112 stores instructions for execution by the processor 102 to perform various actions as will be described herein and is further configured to store a database 114 of user rules and preferences of desired equalization settings based on various metadata tags contained in an audio content signal.

Processor 110 is operable to execute instructions stored in the memory device 112, to detect and/or decode metadata associated with an audio content signal, and to apply user-defined rules stored in the database 114 so as to direct and command settings of the equalizer 104 to achieve user-preferred equalization settings.

It should be understood that processor 110 may be a single processor or multiple processors, and that the processor 110 may be a processor shared with other circuitry and/or processes, such as a processor used for other functionality in the audio output rendering device 102. Memory 112 may be any known memory device capable of storing metadata, user preferences, and user rules as will be discussed in more detail below, and may be memory that is shared with other circuitry and processes, such as memory used for other functionality within the audio output rendering device 102.

In an exemplary embodiment, user preferences and rules may be uploaded and stored in database 114 via a user application on a smart phone or other user device in communication with the automated equalization control module 100 through a wired or wireless interface, allowing a user to build a catalog of preferred settings and rules and periodically upload those to the database 114. In other embodiments the user preferences and rules may be uploaded automatically, or at periodic intervals. In further embodiments, libraries of rules and preferences may be provided by artists, DJ's, or manufacturers for upload to the database 114 by a user. In still further embodiments, preferences and rules may be preloaded in the database 114 at manufacture of the audio output rendering device, with a user further able to view and modify those preferences as desired using a phone or smart device. These and other variations are contemplated by the present invention.

In operation, audio content is provided by a content provider 116. Content provider 116 may be a streaming audio service such as Spotify® or Pandora®, or any other streaming audio service, or may be a downloadable service, such as Itunes®. Content provider 116 may also be a memory device, such as a hard drive, on which a user has stored audio files from any source. Regardless of the content provider 116, audio content is downloaded to, or streamed through, a source device 118, such as a user's smartphone, tablet, laptop, or other device. In the case of downloaded content the source device 118 plays back the audio content on a player application running on the source device, in the case of streaming content the source device 118 runs an application facilitating the streaming.

Regardless of the ultimate source of the content, the source device 118 transmits an audio content signal 120 to the audio output rendering device 102. The audio content signal 120 comprises an audio signal 122 and metadata 124. It should be understood that the audio content signal 120 may be transmitted in any known manner to the audio output rendering device 120, including via wired or wireless transmission. Preferably the audio signal is transmitted wirelessly, such as via a Bluetooth interface.

In the audio output rendering device 102, the sonic characteristics of the audio signal 122 are adjusted by the equalizer 104, with the sonically corrected signal then amplified by the amplifier 106. The amplified signal is then converted to an audible signal by the transducer 108.

Also in the audio output rendering device 102, metadata 124 associated with the audio signal 122 is detected and/or decoded by the processor 110 in the automated equalization module. The processor 110 applies user-defined rules with respect to identified metadata (e.g., a particular “artist”) as stored in database 114 and selects a user-defined defined preferred sound and equalization setting stored in the database 114 based on those applied rules.

Thus, for example, a user may define specific sound equalization settings for songs by artist “Artist 1”. Upon detection of metadata identifying “Artist 1”, the processor 110 selects the sound and equalization settings assigned by the user for Artist 1 as stored in database 114. Similarly, a user may define and store in database 114 desired sound and equalization settings for a metadata genre, such as “classical”. Upon detection by the processor of “classical” in the metadata associated with an audio signal, the processor applies the user's desired settings to the equalizer 104 of the audio output rendering device 102.

Most preferably, the user may prioritize or combine rules to allow selection of desired sound and equalization settings in the case of overlap between detected metadata. For example, a user may prioritize the order in which to apply preferred settings. Thus, if a user has defined preferred sound and equalization settings for the genre of “classical” as well as preferred settings for “Artist 1”, then a secondary user preference or prioritization may indicate that the “artist” metadata takes preference over the “genre” metadata. It should be apparent that tertiary and further prioritizations may similarly be defined by a user.

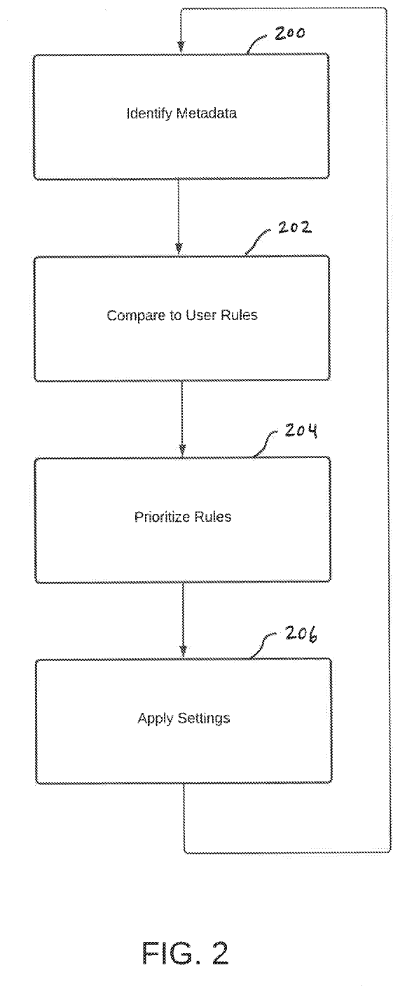

Looking to FIG. 2, in conjunction with FIG. 1, a flowchart depicting an exemplary implementation of the method briefly described above is depicted.

Beginning at block 200, the processor 110 detects and/or decodes and identifies metadata associated with an audio content signal 120. That metadata may be any data or information associated with the audio content, such as artist, song title, album title, etc., such as data typically contained in a common format, such as ID3v1 or ID3v2.

At block 202, upon detection of metadata, the processor 110 searches the database 114 for stored user preferences associated with the identified metadata. For example, if the identified metadata for the field “artist” is “Artist 1”, the processor searches for user sound and equalization settings having that same “Artist 1” identifier. Similarly, if metadata “classical” is identified for the “genre” field, the processor searches for stored user preferences for that field.

At block 204, if the processor has located multiple matching user preferences for the identified metadata, e.g., “artist” and “genre” and “songwriter” all match, the processor searches for, and applies, user-defined rules prioritizing which metadata field should be given priority in selecting a stored user preference for sound and equalization settings. In alternative embodiments, the processor may select the first matching metadata field and select the user preferences associated with that field. In further embodiments, user-defined rules may be more complex, with Boolean and other logical definitions of the priority in which to select the user preference settings.

At block 206, the selected user preference settings are applied to the equalizer of the audio output rendering device such that the user's preferred settings for the audio content are used in the playback of that content.

The process as just described is repeated when the user selects another song or other audio content for playback on the hearable device—i.e., the processor identifies the metadata and applies the user preferred settings so that the audio playback is as desired by the user.

It should be understood that the application of user preferred equalization settings occurs automatically as implemented by the processor 110 and memory 112 using user preferences stored in the database 114 of the automated equalization module 100, with no manual intervention or action by the user. Thus, a user can define a wide range of preferred equalization settings for various artists, genres, etc. and have those preferred settings applied automatically just by playing the audio content. It should be apparent that because the settings are applied by the identified metadata that such settings can be applied proactively, i.e., even if the user has never played a particular song before.

Thus, it can be seen that in this first exemplary embodiment an audio rendering device, such as a hearable device, can operate essentially autonomously to apply user equalization preferences stored in the database 114 as audio content is played on the device.

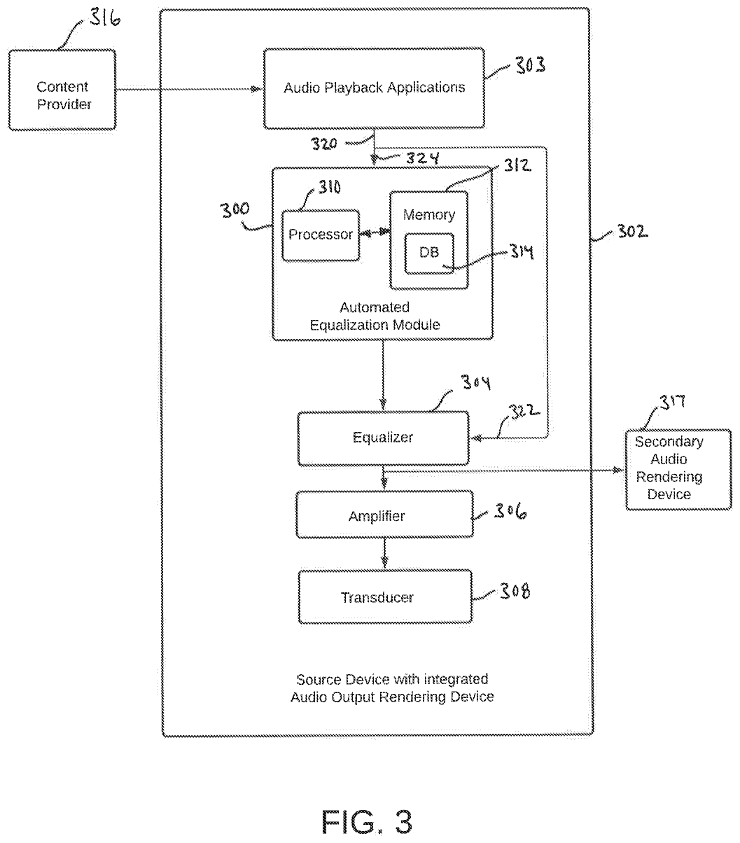

FIG. 3 depicts a second exemplary embodiment in which the automated equalization module is integrated into a source device which includes an audio output rendering device. The operation of the module in identifying metadata and adjusting equalization settings in response is generally the same as discussed above with respect to the embodiment described in FIG. 1, but in this embodiment, the source device receives content from a content provider for playback via one or more audio playback applications. The user preferences and rules are stored in a database either in memory of the automated equalization module or in memory of the source device. As described with respect to the embodiment of FIG. 1, the memory and processor may be shared between the source device, automated equalization module, and audio output rendering device.

Looking still to FIG. 3, an automated equalization control module in accordance with a second exemplary embodiment of the present invention is depicted by the numeral 300. In this embodiment, the automated equalization control module 300 is embedded in a source device 302 that includes an integrated audio output rendering device to transform audio signals to user hearable sound waves. The source device 302 may be any type of device capable of playing back audio content, such as a smartphone, laptop, tablet, smart headphones, hearables, and the like, wherein the integrated audio output rendering device is operable to render the altered audible sound as previously described, and/or to further forward the newly equalized or optimized audio output, either in analog or digital format, on to additional devices via wired or wireless connection.

The source device 302 is operable run audio playback applications 303, such as music playback or streaming applications. The source device includes an equalizer module 304 operable to adjust the sonic characteristics of an audio signal to achieve a desired sound for a listener, an amplifier 306 to amplify an audio signal to a desired level, and a transducer 308, such as a speaker, to translate the audio signal to an audible sound wave.

It should be understood that these modules and functions may be accomplished via hardware, software, and combinations thereof. It should be further understood that the identification of a separate equalizer 304, amplifier 306, and transducer 308 in the source device 302 is for exemplary and explanatory purposes, and that in practice there may be overlap between the hardware and/or software used in implementing those modules and functions. It should be further understood that the term equalizer 304 may encompass any type of audio signal manipulation, including audio effects, spatial characteristics, time delays, or any other type of audio signal processing.

Regardless of the physical or virtual configuration the automated equalization control module 303 is operable to set, reset, and or adjust the equalizer 304 to achieve desired settings of that equalizer module.

Looking still to FIG. 3, automated equalization module 300 comprises a processor 310 in communication with a memory device 312. Memory device 312 stores instructions for execution by the processor 310 to perform various actions as will be described herein and is further configured to store a database 314 of user rules and preferences of desired equalization settings based on various metadata tags contained in an audio content signal.

Processor 310 is operable to execute instructions stored in the memory device 312, to detect and/or decode metadata associated with an audio content signal, and to apply user-defined rules stored in the database 314 so as to direct and command settings of the equalizer 304 to achieve user-preferred equalization settings.

It should be understood that processor 310 may be a single processor or multiple processors, and that the processor 310 may be a processor shared with other circuitry and/or processes, such as a processor used for other functionality in the source device 102. Memory 312 may be any known memory device capable of storing metadata, user preferences, and user rules as will be discussed in more detail below, and may be memory that is shared with other circuitry and processes, such as memory used for other functionality within the audio output rendering device 302, or memory or storage accessed through the cloud.

In an exemplary embodiment, user preferences and rules may be uploaded and stored in database 314 via a user application on the source device 302 smart phone or other user device in communication with the automated equalization control module 300, allowing a user to build a catalog of preferred settings and rules and periodically upload those to the database 314. In other embodiments the user preferences and rules may be uploaded automatically, or at periodic intervals by the source device. In further embodiments, libraries of rules and preferences may be provided by artists, DJ's, or manufacturers for upload to the database 314 by a user. In still further embodiments, preferences and rules may be preloaded in the database 314 at manufacture of the audio output rendering device, with a user further able to view and modify those preferences as desired using a phone or smart device. These and other variations are contemplated by the present invention.

In operation, audio content is provided by a content provider 316. Content provider 316 may be a streaming audio service such as Spotify® or Pandora®, or any other streaming audio service, or may be a downloadable service, such as Itunes®. Content provider 316 may also be a memory device, such as a hard drive, on which a user has stored audio files from any source. Regardless of the content provider 116, audio content is downloaded to, or streamed to, the source device 302. In the case of downloaded content the source device 302 plays back the audio content on a player application 303 running on the source device, in the case of streaming content the source device 302 runs an application 303 facilitating the streaming.

Regardless of the ultimate source of the content, the playback application 303 running on the source device 302 generates an audio content signal 320. The audio content signal 320 comprises an audio signal 322 and metadata 324.

In the integrated audio output rendering device portion of the source device 302, the sonic characteristics of the audio signal 322 are adjusted by the equalizer 304, with the sonically corrected signal then amplified by the amplifier 306. The amplified signal is then converted to an audible signal by the transducer 308. If a user prefers to use an external or secondary audio rendering device 317, a jack or connector on the source device 302 allows that optional connection.

Metadata 324 associated with the audio signal 322 is detected and/or decoded by the processor 310 in the automated equalization module. The processor 310 applies user-defined rules with respect to identified metadata (e.g., a particular “artist”) as stored in database 314 and selects a user-defined defined preferred sound and equalization setting stored in the database 314 based on those applied rules.

The application of the rules and preferences are the same as previously described with respect to the first exemplary embodiment of FIG. 1 with reference to FIG. 2, and thus for brevity will not be repeated here.

It should be understood that the application of user preferred equalization settings occurs automatically as implemented by the processor 310 and memory 312 using user preferences stored in the database 314 of the automated equalization module 300, with no manual intervention or action by the user. Thus, a user can define a wide range of preferred equalization settings for various artists, genres, etc. and have those preferred settings applied automatically just by playing the audio content. It should be apparent that because the settings are applied by the identified metadata that such settings can be applied proactively, i.e., even if the user has never played a particular song before.

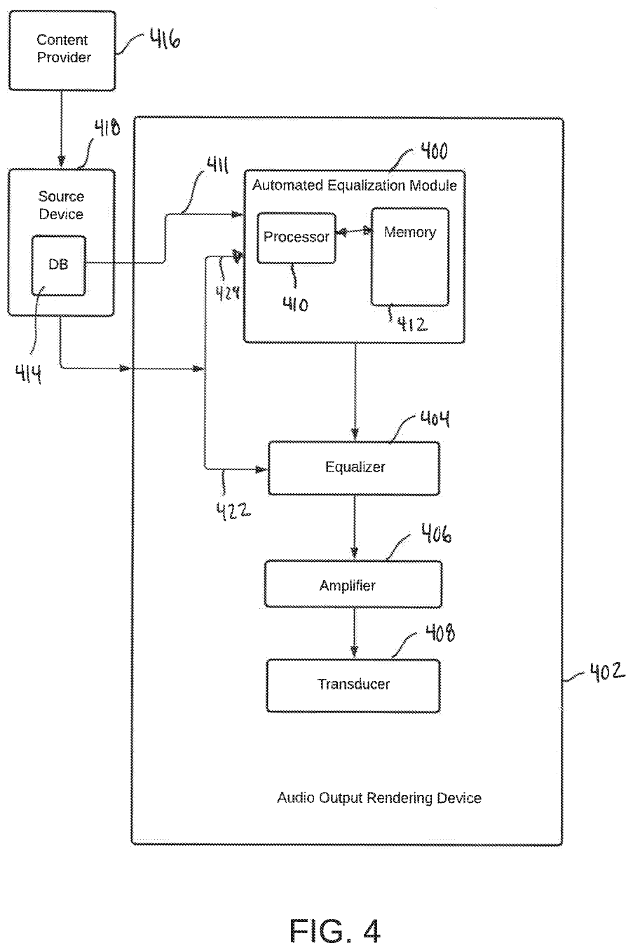

Turning to FIG. 4, an automated equalization control module in accordance with a third exemplary embodiment of the present invention is depicted by the numeral 400. This embodiment is similar to that previously described with respect to FIG. 1, with the automated equalization control module embedded in an audio output rendering device 402.

As in the prior embodiment, the rendering device 402 includes an equalizer 404, amplifier 406 and transducer 408, as previously described. Automated equalization module 400 comprises a processor 410 in communication with a memory device 412. And as in the prior described embodiment, a content provider 416 provides content to a source device 418 in a manner as previously described.

In this embodiment, database 414 resides on the source device, external to the audio output rendering device and the database information is available to the processor 410 over a wired or wireless datalink 411.

Thus, in this embodiment, the determination of preferred user settings occurs in the manner as previously described, with the processor accessing the database 414 residing on the external source device rather that residing in internal memory. With the database thus residing, a user of the source device 418 may update, change, set or reset the preferences and rules in the database through operation of the source device.

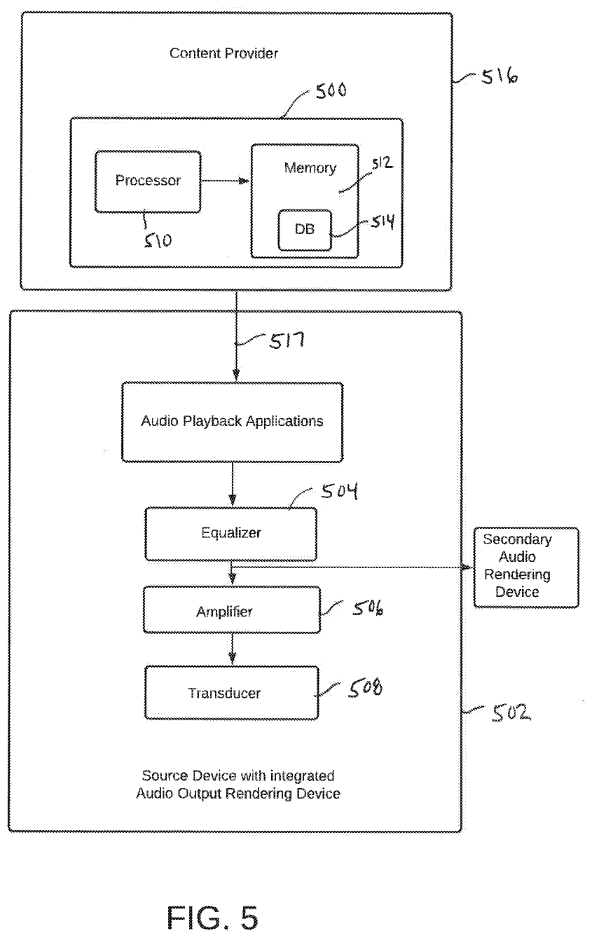

Turning to FIG. 5, an automated equalization control module in accordance with a fourth exemplary embodiment of the present invention is depicted by the numeral 500. This embodiment is similar to that previously described with respect to FIG. 3. In this embodiment, the automated equalization control module resides at the content provider such that the rules and preferences are applied at the content provider, with the audio stream provided by the content provider already having the user's equalization preferences applied.

As in the prior embodiment, the source device with integrated rendering device 502 includes an equalizer 504, amplifier 506 and transducer 508, as previously described. Automated equalization module 500 resides at the content provider 516 and comprises a processor 510 in communication with a memory device 512. A database 514 having user equalization preferences and rules as previously described resides in the memory device 512, or in other memory at the content provider 516.

Thus, in this embodiment, the determination of preferred user settings occurs in the manner as previously described, but occurs at the content provider 516. Thus, in a preferred embodiment, the streaming signal 517 of audio content form the content provider arrives at the source device 502 with the user preferred equalization settings and rules already applied.

In an alternative embodiment, the user preferences and rules are applied at the content provider 516, with an instruction file then sent to the source device 502 operable to adjust the equalizer 504 at the source device 502 to achieve the desired equalization settings. Thus, while the processing of rules and preferences occurs at the content provider 516, the application of those rules may be either to the audio signal prior to transmission from the service provider, or may be in the form of an instruction file for the source device to perform the equalization settings.

In further embodiments, a user may transfer or receive preferences to or from other users. For example, an artist, DJ or producer may make available his or her preferred equalization settings for songs, catalogs of music, playlists, and the like, and allow users of particular compatible hearables or user devices to access and use those preferences. And, because the settings are based on metadata, those shared preferences would be applied regardless of the source of playback for those songs.

In further alternative embodiments, sensors on the hearable device may provide further metadata or signals to the automated equalization control module which may be incorporated into the user rules for applying equalization settings. For example, a microphone or sound pressure level sensor incorporated on a wearable hearable device, such as headphones, may provide a signal indicative of an ambient noise level to the automated equalization control module with a user rule providing that when the ambient noise level is above a particular threshold, the equalization level may be adjusted to increase a desired frequency band and/or the volume may be adjusted to allow a user to more easily hear, for example, an audio book.

Many different arrangements of the various components depicted, as well as components not shown, are possible without departing from the scope of the description provided herein. Embodiments of the technology have been described with the intent to be illustrative rather than restrictive. Alternative embodiments will become apparent to readers of this disclosure after and because of reading it. Alternative means of implementing the aforementioned can be completed without departing from the scope of exemplary embodiments. Identification of structures as being configured to perform a particular function in this disclosure is intended to be inclusive of structures and arrangements or designs thereof that are within the scope of this disclosure and readily identifiable by one of skill in the art and that can perform the particular function in a similar way. Certain features and sub-combinations are of utility and may be employed without reference to other features and sub-combinations and are contemplated within the scope of exemplary embodiments described herein.

1. A system for customizing sound and equalization for audio devices, comprising:
a sound and equalization module comprising a processor and a memory device, wherein the sound and equalization module has an input for receiving an audio content signal, and wherein the memory device has stored thereon executable instructions that, when executed by the processor, cause the sound and equalization module to perform operations comprising:
identifying metadata transmitted in the audio content signal;
correlating identified metadata with user equalization preferences; and
applying user equalization preferences to equalization circuitry of a hearable device.

2. The system of claim 1, wherein the user equalization preferences are stored on the memory device.

3. The system of claim 1, wherein the user equalization preferences are stored on a user device.

4. The system of claim 1, wherein the memory device has stored thereon executable instructions that, when executed by the processor, cause the sound and equalization module to perform further operations comprising:
applying user-defined rules to prioritize application of a plurality of user-defined preferences.

5. The system of claim 4 wherein the user-defined rules are stored on the memory device.

6. The system of claim 4 wherein the user defined rules are stored on a user device.

7. A method for customizing sound and equalization for audio devices, comprising:
identifying metadata in an audio content signal;
correlating identified metadata with user equalization preferences; and
applying user equalization preferences to equalization circuitry of a hearable device.

8. The method of claim 7, wherein correlating identified metadata with user equalization preferences comprises:

9. The method of claim 7, further comprising:
applying user-defined rules to prioritize application of a plurality of user-defined preferences.

10. The method of claim of claim 7, wherein applying user equalization preferences to equalization circuitry of a hearable device comprises:
adjusting software settings, hardware settings, and combinations thereof on the hearable device.

11. A hearable device having customized sound and equalization, comprising:
amplifier circuitry for amplifying an audio portion of an audio content signal;
an equalizer for adjusting sonic characteristics of the audio portion; and
a sound and equalization module comprising a processor and a memory device, wherein the memory device has stored thereon executable instructions that, when executed by the processor, cause the sound and equalization module to perform operations comprising:
identifying metadata transmitted in the audio content signal;
correlating identified metadata with user equalization preferences; and
applying correlated user equalization preferences to the equalizer.

12. The hearable device of claim 11, wherein the user equalization preferences are stored on the memory device.

13. The hearable device of claim 11, wherein the user equalization preferences are stored on a user device.

14. The hearable device of claim 11, wherein the equalizer comprises hardware circuitry, software, and combinations thereof.

15. The hearable device of claim 11, further comprising:
a transducer operable to generate an audible sound corresponding to the audio portion of the audio content signal.
